(19) United States
(12) Patent Application Publication
(10) Pub. No.: US 2011/0043230 A1
(43) Pub. Date: Feb. 24, 2011

(54) MOISTURE MONITORING DEVICE AND METHOD

(75) Inventor: David L. Morton, Sandy, UT (US)

Correspondence Address: Fraser D. Roy;WORKMAN NYDEGGER, 60 East South Temple, 1000 Eagle Gate Tower, Salt Lake City, UT, 84111, US

(73) Assignee: FERTILE EARTH SYSTEMS, INC., Sandy, UT (US)

(21) Appl. No.: 12/726,305

(22) Filed: Mar. 17, 2010

Related U.S. Application Data
(63) Continuation-in-part of application No. 12/611,053, filed on Nov. 2, 2009.
Application No. 12/611,053 is a continuation-in-part of application No. 29/329,073, filed on Dec. 8, 2008, now Pat. No. D609588.
Application No. 29/329,073 is a continuation-in-part of application No. 12/491,121, filed on Jun. 24, 2009.
Application No. 12/491,121 is a continuation-in-part of application No. 29/329,073, filed on Dec. 8, 2008, now Pat. No. D609588.
(60) Provisional application No. 61/110,368, filed on Oct. 31, 2008.
(60) Provisional application No. 61/120,789, filed on Dec. 8, 2008.
(60) Provisional application No. 61/110,368, filed on Oct. 31, 2008.
(60) Provisional application No. 61/120,789, filed on Dec. 8, 2008.

(51) Int. Cl. G01R 27/08

(52) U.S. Cl. 324/694

(57) ABSTRACT

A moisture monitoring device that measures the dielectric constant of a material to provide an indication of the moisture content of a material. The moisture monitoring device can provide an instantaneous indication of the moisture content of a material (e.g., soil). The moisture monitoring device can include a number of interchangeable decorative to allow a user to customize the appearance of the device. The moisture monitoring device can be used in conjunction with a moisture monitoring system that can be used to control a watering system (e.g., an irrigation system). A method for providing an instantaneous indication of the moisture content of a material is also disclosed.

### CROSS-REFERENCE TO RELATED APPLICATIONS

This application is a continuation-in-part of U.S. patent application Ser. No. 12/611,053 filed 2 Nov. 2009 and entitled “WIRELESS MOISTURE MONITORING DEVICE AND METHOD,” which is a continuation-in-part of U.S. Design patent application Ser. No. 29/329,073 filed 8 Dec. 2008 and entitled “SOIL MOISTURE MONITORING DEVICE,” now U.S. Design Pat. No. D609,588 issued 9 Feb. 2010, the entireties of which are incorporated herein by reference. U.S. patent application Ser. No. 12/611,053 also is a continuation-in-part of U.S. patent application Ser. No. 12/491,121 filed 24 Jun. 2009 and entitled “MOISTURE MONITORING DEVICE AND METHOD,” which claims the benefit of U.S. Provisional Application Ser. No. 61/110,368 filed 31 Oct. 2008 and entitled “SOIL MOISTURE MONITORING DEVICE AND METHOD,” which claims the benefit of U.S. Provisional Application Ser. No. 61/120,789 filed 8 Dec. 2008 and entitled “WIRELESS MOISTURE MONITORING SYSTEM AND METHOD,” and which is a continuation-in-part of U.S. Design patent application Ser. No. 29/329,073 filed 8 Dec. 2008 and entitled “SOIL MOISTURE MONITORING DEVICE,” now U.S. Design Pat. No. D609,588 issued 9 Feb. 2010, the entireties of which are incorporated herein by reference. U.S. patent application Ser. No. 12/611,053 also claims the benefit of U.S. Provisional Application Ser. No. 61/110,368 filed 31 Oct. 2008 and entitled “SOIL MOISTURE MONITORING DEVICE AND METHOD,” the entirety of which is incorporated herein by reference. U.S. patent application Ser. No. 12/611,053 also claims the benefit of U.S. Provisional Application Ser. No. 61/120,789 filed 8 Dec. 2008 and entitled “WIRELESS MOISTURE MONITORING SYSTEM AND METHOD,” the entirety of which is incorporated herein by reference.

### BACKGROUND OF THE INVENTION

1. Technical Field

The present invention relates generally to moisture sensing. More particularly, embodiments of the present invention relate to improved moisture monitoring devices and methods which warn a caretaker of the degree to which a plant needs to be watered.

2. The Relevant Technology

The ability to sense and measure moisture in a medium can provide significant benefits. Measuring the water content of a medium can be used, for example, to control sprinkling systems or to implement water conservation techniques. Several methods and devices for measuring water content or moisture of water permeable media or materials such as soil have traditionally been used.

One technique is to measure the dielectric constant of the medium under test. The dielectric constant of water is quite high at about 80. Materials or media such as soil, however, typically only have a dielectric constant of about 4. Changes in the water content of a particular medium will cause a change in the dielectric constant of the medium.

Unfortunately, the expense, power consumption, and sophisticated nature of conventional devices used in measuring moisture content of materials has been problematic. These traditional devices are often not suitable for in-home use by the average consumer to monitor the moisture content of a typical indoor potted plant's soil. At the same time these devices are often unsuitable for large scale implementations because of at least the cost and power consumption.

### BRIEF SUMMARY OF THE INVENTION

Embodiments of the present invention are directed to a moisture monitoring device that can be used to measure the moisture content (e.g., water content) of a medium or material (e.g., soil). Embodiments of the present invention also relate to a moisture monitoring system that can be used to control a watering system (e.g., an irrigation system) and a method for providing an instantaneous or current indication of the moisture content of a material.

In one embodiment, the moisture monitoring device may generally be configured as a device having a moisture sensing probe at one end that can be vertically inserted (e.g., at least partially submerged) in a material, while the other end includes circuitry for displaying the moisture content of the material such as by lighting one or more Light Emitting Diodes (LEDs), displaying images on a Liquid Crystal Display (LCD), or otherwise presenting a visual representation or indication of the moisture content of the material. The device can be configured to provide continuous or periodic indications of the moisture level of the material as well as to provide an instantaneous or current indication of the moisture level of the material. In addition to displaying an indication of the moisture content of material, the device can be configured to provide an indication that the moisture level in the material exceeds a specified threshold value. The device is further configured to allow a consumer to customize the device by interchanging decorative tops.

In an additional embodiment, the invention is directed to a packaging assembly in which the device may be displayed in such a manner as to allow a prospective purchaser to test the device (i.e., activate a demonstration mode) without removing it from the packaging. In yet another embodiment, the device can include a first sensing mode wherein the device is calibrated for detection of moisture in a first medium type and a second sensing mode wherein the device is calibrated for detection of moisture in a second medium type. Additionally, the device can be configured to allow the user to toggle between the demonstration mode, the first sensing mode mode, and the second sensing mode by depressing the activation button for at least about two seconds, for example.

An exemplary moisture monitoring system can include an irrigation control module communicatively coupled to one or more valves and one or more irrigation devices via one or communication lines, one or more moisture monitoring devices (i.e., moisture probes) for detecting moisture content in a material when each of the one or more devices is at least partially submerged in the material, and a moisture control module in communication with the irrigation control module and the one or more moisture monitoring devices. The moisture control module can further include processing circuitry configured for receiving a signal from the one or more moisture monitoring devices and manipulating the signal for delivery to the irrigation control module to initiate activation and deactivation of the one or more irrigation devices based upon the detected moisture content.

In one embodiment, each of the one or more moisture monitoring devices can include a probe that is inserted into a material and moisture sensing circuitry configured to produce a first signal that varies in magnitude with the moisture content of the material, and a first transceiver communicably coupled to the moisture sensing circuitry for processing the first signal and communicating a second signal to the moisture control module, wherein the first and second signals each have a magnitude that is proportional to the moisture content of the material. In one embodiment, the magnitude of the signal can also vary according to the depth that the probe is inserted in the material.

In one embodiment, a method for measuring moisture content is disclosed. The method can include (1) providing one or more moisture monitoring devices for detecting moisture content in a material, each of the one or more devices including a moisture probe and moisture sensing circuitry, (2) partially submerging the one or more probes in the material, (3) triggering a switch to activate a driver so as to receive a signal from the moisture sensing circuitry, (4) converting the received signal to a current having a magnitude that is proportional to the signal; and (5) transmitting the current to the one or more display devices for activating the one or more display devices, wherein activating the one or more display devices provides an instantaneous indication of the moisture content of the material.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

To further clarify at least some of the advantages and features of the present invention, a more particular description of the invention will be rendered by reference to specific embodiments thereof which are illustrated in the appended drawings and exhibits, which are incorporated herein by this reference. It is appreciated that these drawings and exhibits depict only illustrated embodiments of the invention and are therefore not to be considered limiting of its scope. The invention will be described and explained with additional specificity and detail through the use of the accompanying drawings and exhibits in which:

FIG. 1A illustrates a perspective view of a moisture monitoring device according to one embodiment of the present invention;

FIG. 1B is an exploded perspective view of the moisture monitoring device of FIG. 1A;

FIG. 1C illustrates a rear perspective view of the moisture monitoring device of FIG. 1A;

FIG. 2A illustrates a perspective view of an embodiment of a transmission line probe where a flexible transmission line is mounted on a rigid support;

FIG. 2B illustrates a perspective view of an embodiment of a transmission line probe where a flexible transmission line is embedded in a circuit board;

FIG. 3A illustrates perspective views of a moisture monitoring device having an interchangeable decorative top according to one embodiment of the present invention;

FIG. 3B illustrates the changing of an interchangeable decorative top according to one embodiment of the present invention;

FIG. 4 is a diagrammatic drawing of an exemplary moisture monitoring system in which the principles of the present invention may be employed;

FIG. 5 illustrates a block diagram of an example of a moisture sensing circuit according to one embodiment of the present invention;

FIG. 6 illustrates a circuit diagram of a filter according to one embodiment of the present invention;

FIG. 7 illustrates a circuit diagram of a passive peak detector according to one embodiment of the present invention;

FIG. 8 illustrates a block diagram showing a multi-segment transmission line; and

FIG. 9 illustrates an embodiment of a moisture monitoring device incorporating a capacitive probe.

### DETAILED DESCRIPTION

Embodiments of the present invention are directed to a moisture monitoring device that can be used to measure the moisture content (e.g., water content) of a material (e.g., soil). The present invention also includes a moisture monitoring system that can be used to control a watering system (e.g., an irrigation system) and a method for providing an instantaneous or current indication of the moisture content of a material. Although embodiments of the invention are described in the context of water or moisture, one of skill in the art can appreciate, with the benefits of the present disclosure, that the content of other liquids or other materials could be quantified, in part by their impact on the dielectric constant.

In one embodiment, the moisture monitoring device may generally be configured as a device having a moisture sensing probe at one end that can be vertically inserted (i.e., at least partially submerged) in a material, while the other end includes circuitry for displaying the moisture content of the material such as by lighting one or more Light Emitting Diodes (LEDs), displaying images on a Liquid Crystal Display (LCD), or otherwise presenting a visual representation or indication of the moisture content of the material.

The device can be configured to provide continuous or periodic indications of the moisture level of the material as well as to provide an instantaneous or current indication of the moisture level of the material. The device may also be able to provide a history of how the moisture content changes over time in the material. In addition to displaying an indication of the moisture content of material, the device can also be configured to provide an indication that the moisture level in the material exceeds a specified threshold value. The device is further configured to allow a consumer to customize the device by interchanging decorative tops

In an additional embodiment, the invention is directed to a packaging assembly in which the device may be displayed in such a manner as to allow a potential purchaser to test the device without removing it from the packaging.

### I. Moisture Monitoring Device

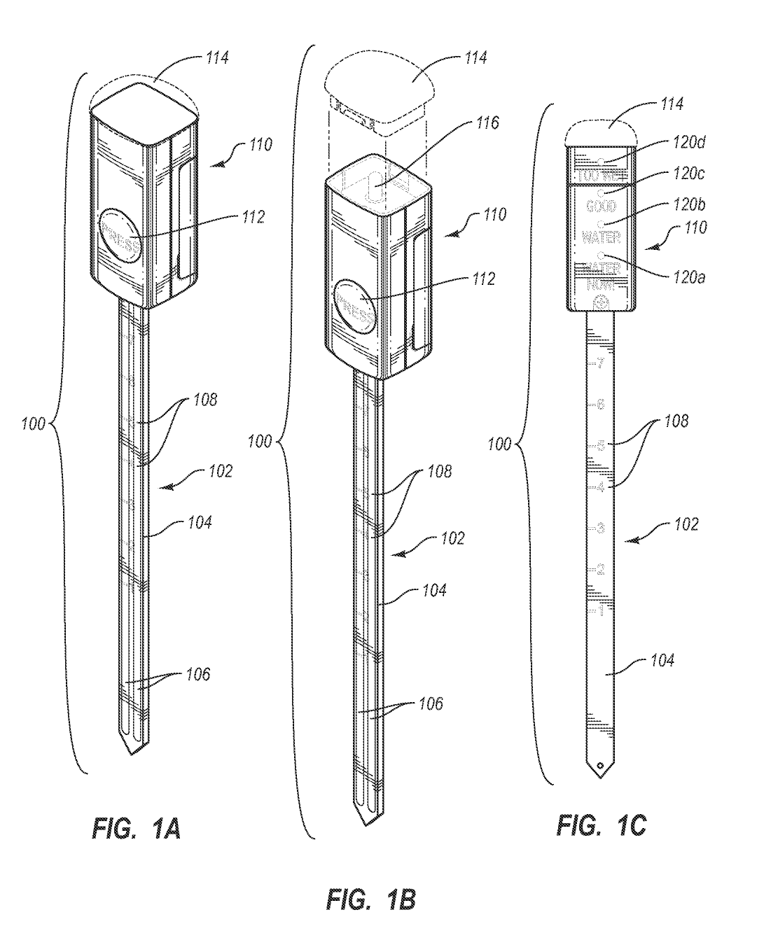

Referring now to FIGS. 1A-1C, various views of an exemplary moisture monitoring device 100 are illustrated. In general, the more water a material contains, the higher its dielectric constant will be. The moisture monitoring device can measure the dielectric constant of a material and use the measured dielectric constant to detect and quantify the moisture level in the material.

In one embodiment, a moisture monitoring device 100 according to the present invention includes a probe 102 and a housing 110. The probe 102 includes a rigid probe body 104 and a transmission line 106. For instance, the probe body 104 can include a single or multiple layer electronic circuit printed circuit board with traces formed thereupon, which can function as a transmission line 106. In one embodiment, the probe can include printed depth indicia shown, for example at 108.

In one aspect, the probe 102 can be formed from a standard circuit board assembly consisting of a number of circuit boards bonded together to form the rigid probe body (e.g., probe body 104). The transmission line 106 can be etched on one side of a first circuit board. A second pieced of printed circuit board material, similar in size and thickness to the first, can then be bonded to the first board so the transmission line is insulated from the medium in which it is placed. Additionally, an epoxy sealant can be applied to the rigid probe body 104 to further seal and protect the circuit components. While it is generally desirable to protect the probe circuitry from corrosion by sealing it from the medium, other configurations of the probe circuitry are possible. For instance, the transmission line 106 can be formed from an inexpensive, flexible wire material that is applied to the rigid probe body 104 to facilitate inserting the probe 102 into the medium.

The moisture monitoring device 100 is configured to detect the moisture content of a material when the probe 102 is inserted into the material. As will be discussed in greater detail in reference to the moisture sensing circuitry, the moisture monitoring device 100 can detect the moisture of the material by delivering a signal through the transmission line 106 of the probe. The ability of the device 100 to propagate the signal can be affected both by the water content of the material and by the depth that the probe 102 is inserted into the material. As such, the response of the probe 102 can be calibrated for different soil types by selecting the length that the probe 102 is inserted into the soil based on the soil type and/or the plant type.

For instance, the depth indicia 108 can allow a user to adapt the device 100 to different plant types and watering habits. For example, the probe 102 can be inserted less deeply for wetter soil types (e.g., depth marks 1-3 for tropical plants), whereas drier soil types may require the probe 102 to be inserted more deeply (e.g., depth marks 5-7 for desert plants), or in between (e.g., depth marks 3-5) for typical potting soils.

In one embodiment, the probe 104 of the moisture monitoring device 100 can further include a distal end having an active zone that includes at least a portion of the moisture sensing circuitry and inactive zone that is disposed proximally to the active zone (i.e., more toward the surface of the medium that the probe is inserted into). For example, the active zone can be approximately 3 inches in length and the inactive zone can be approximately 2 inches in length. Inserting the probe substantially vertically into the soil and placing the proximal end of the inactive zone at the soil surface helps to ensure that the active zone is in the relevant “root zone” for a variety of plants. This ensures that moisture measurements are occurring in the “root zone.” Inserting the probe 104 vertically into the soil also increases ease of use for the consumer and minimizes soil disturbance. This can provide a more accurate estimate of the moisture content in the region of the soil where plants typically need it most (i.e., the root zone). This can also encourage deep watering, which promotes water conservation, deep root growth, and increased plant vigor.

In one embodiment, the device 100 can be configured to provide a readout proportional to an average of the moisture content in the active zone. In conjunction with the depth of the active zone, this can provide increased accuracy in the estimate of the moisture content of the soil in the root zone. As was discussed in the previous paragraph, this can further encourage deep watering, which promotes water conservation, deep root growth, and increased plant vigor. Averaging the moisture reading over the active zone also provides for a degree of flexibility with respect to the depth that the probe 104 is inserted into the soil. That is, because the moisture reading is being averaged over a vertical depth range, the device 100 is less sensitive to the depth of insertion. Moreover, the user can easily adjust the device 100 to a particular watering situation by inserting the probe 104 more deeply into the soil (e.g., for a deeply rooted plant) or withdrawing the probe 104 slightly from the soil (e.g., for a plant having shallow roots).

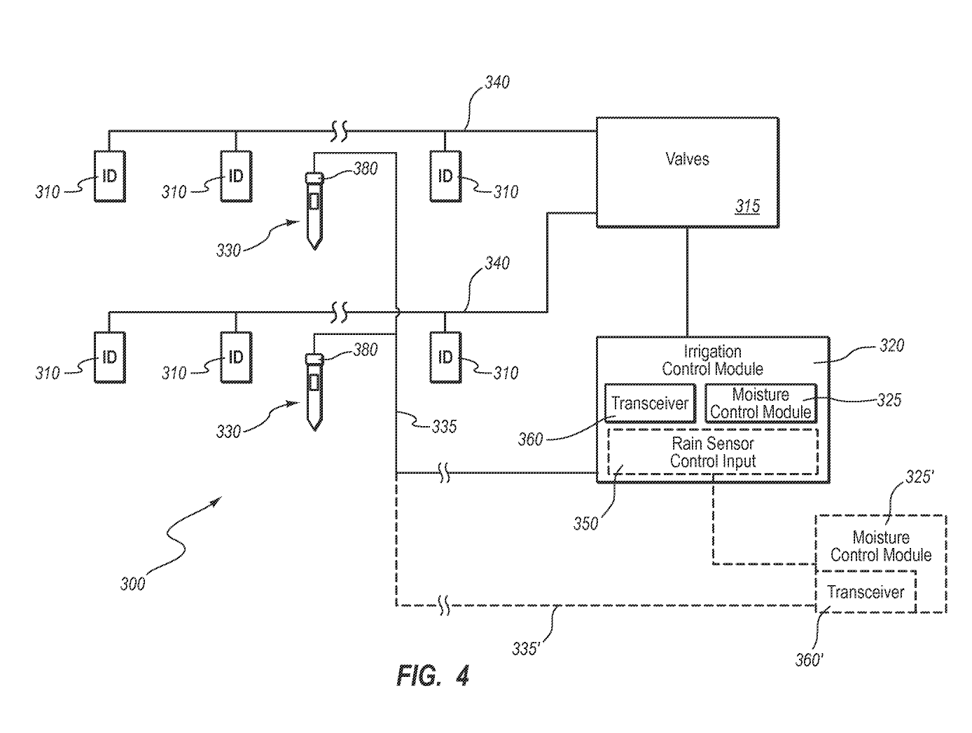

In one embodiment, the housing 110 includes a button 112 for actuating the moisture monitoring device 100 and a cover 114. The housing 110 can also include or contain moisture sensing circuitry, which will be discussed in greater detail below in reference to FIGS. 4-9. FIG. 1B illustrates the device 100 with the cover 114 removed exposing an indicator 116, which can serve as a display device. In one embodiment, cover 114 can be interchanged with one or more different, decorative covers.

The indicator 116 can be configured, for example, to indicate that device 100 is active. The indicator 116 can be an LED, LCD, or another display device that is configured to indicate the moisture level of the material. In one embodiment, the display device (e.g., indicator 116) is disposed within the housing 110 of the device 100 such that the light emitted by the display device exits through the top of the housing 110 and through a cap or removable cover 114, as further described below.

The signal output from the transmission line 106 and/or the moisture sensing circuitry can be fed to a driver that drives one or more of the display devices to display an indication of the moisture content of the material. In one embodiment, the driver may be an LED driver that drives a multicolor LED with a color hue that can be proportional to the signal, thus providing the indication of the moisture content of the measured material. Any suitable LED driver and LED may be used to provide the indication. For example, multicolor LEDs can be composed of several closely placed LEDs which each emit one primary color from the spectrum. Various color schemes can be used for displaying the relative moisture level of the soil. For example, red may be used to indicate excessive soil dryness, yellow to indicate water is needed, green to indicate ideal water content, and blue to indicate over-watering.

The LED driver can be implemented in any suitable manner to provide the appropriate signal to drive the LEDs. For the purpose of conserving power, the LED driver can be implemented such that it only turns on the LEDs after a particular dryness threshold is reached. The LEDs may then be flashed at a periodic slow rate and at an appropriate color to indicate the moisture content of the soil. Such an approach can conserve the battery life of the moisture sensing device. Alternatively, one or more LEDs may remain on during use, with the particular color of the illuminated LED identifying the moisture content of the soil.

In another embodiment, the driver may be an LCD driver which drives an LCD to display the indication of the moisture content of the measured material. Any suitable LCD may be used. The LCD driver may include logic for determining an appropriate indication to display on the LCD based on the signal received from the circuitry. The indication may be provided by displaying text, images, colors, or combinations of both on the LCD.

In an alternative embodiment of the present invention shown in FIG. 1C, housing 110 further includes a series of water level indicators 120a-120d that can indicate the water content of the material and/or whether or not a plant needs water. For example, water level indicator 120a can include a colored light (e.g., a red LED) and corresponding text printed on the housing 110 indicating that the plant needs to be watered immediately; water level indicator 120b can include a second colored light (e.g., a yellow LED) and corresponding text printed on the housing 110 indicating that the plant needs water, but to a lesser extent that is indicated by water level indicator 120a; water level indicator 120c can include a third colored light (e.g., a green LED) and corresponding text printed on the housing 110 indicating that the plant does not need water (i.e., the water level in the soil is in a range acceptable for maintaining plant health and growth); and water level indicator 120c can include a fourth colored light (e.g., a blue LED) and corresponding text printed on the housing 110 indicating that the plant has been over watered.

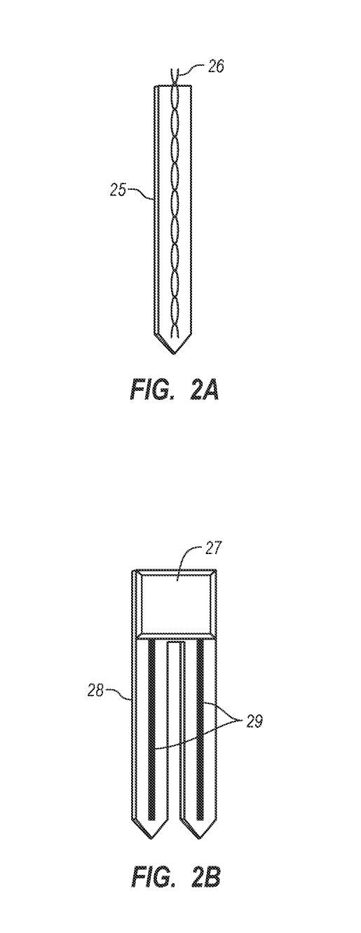

FIG. 2A shows another type of probe body that could be used. This probe can include an inexpensive flexible transmission line such as a twisted pair 26, and a rigid elongated brace or support 25, whereby the transmission line may be easily inserted into a bulk material.

FIG. 2B shows another type of probe body that can be used. It should be noted that this is just one example, and that many other circuit board shapes and geometries can be used. This probe can include a single or multiple layer electronic circuit printed circuit board 28 with traces 29 formed thereupon. These traces 29 function as transmission lines, on the circuit board 28. The sensor's electronic circuit can also be formed on the circuit board (not shown) and optionally encapsulated in a water tight covering 27.

### II. Instantaneous or Current Readings of Moisture Content

In addition to allowing for continuous or periodic indications of the moisture content of a material, the present invention provides a way for a consumer to receive an instantaneous or current indication of moisture content. For example, in response to a consumer's input, such as pressing button 112, the device 100 can provide an instantaneous indication of the current moisture content of the material that the probe is inserted into by driving the display device for a specified duration of time. In this manner, the consumer may know the current moisture content of the material at any time, but without requiring that the display device be constantly driven by the circuitry. In this manner, battery life can be significantly extended.

In one embodiment, the device is configured to provide instantaneous readings in both an on state and an off state. While in the on state, the device can continuously monitor the moisture content of the material surrounding the probe, whereas while in the off state, the device will only monitor the moisture content in response to a consumer's input requesting an instantaneous reading. The device may be toggled from the on state to the off state and vice versa by holding button 112 for a predefined period of time, such as three seconds. An indication of the transition from one state to the other may be provided such as by flashing the LEDs a number of times with a certain color (e.g. three red flashes when transitioned to an off state and three green flashes when transitioned to an on state). It will be understood that other periods of time used to transition from on state to off state, or vice versa, are possible. For instance, durations greater or lesser than three seconds may be used.

### III. Detecting Overwatering

Another benefit of the instantaneous indication of moisture content is the ability to detect over watering. For example, when a consumer initially waters a plant, the moisture content of the soil can be excessive. As a result, an instantaneous reading of moisture content should indicate that the plant has been overwatered (e.g. by providing a blue LED output). However, in order to detect whether an appropriate amount of water was added, the consumer may perform a subsequent instantaneous reading after a period of time, such as after about 15 minutes, about 30 minutes, about an hour, or similar periods of time. It will be understood that the period of time between watering and subsequent reading can vary based upon the particular type of plant growing in the soil and particular climate conditions. As such, times shorter or longer than those indicated above are also possible and would be identifiable to one skilled in the art in view of the teaching provided herein. If the subsequent instantaneous reading indicates that the water content of the soil is now ideal, the consumer may know that the amount of water added previously was an appropriate amount. In contrast, if the subsequent reading indicates that the water content is still too high (e.g. the LED is still blue), the consumer may know that the amount of water added previously was excessive, and may adjust the amount for future waterings. The device can thus effectively teach a user regarding the appropriate amount of water. This can lead to the conservation of water.

### IV. Interactive Packaging

Another benefit of the instantaneous read feature of the present invention is its ability to allow a potential purchaser to test the device 100 while it is still in its packaging. For example, suitable packaging may include apertures, holes, or openings to allow a consumer to test the device 100 by grasping the probe 102 while actuating device 100 by pushing button 112. In response, the device 100 can sense the moisture content of the consumer's fingers and drive the display device to display an indication of the moisture content accordingly. As described above, the device may be configured such that it may remain in an off state while still being capable of providing the instantaneous reading. Thus, battery life can be preserved while still providing the benefit of allowing the potential purchaser to realize the ease of using the device. This feature provides substantial benefits over prior art devices which were much more complex and expensive in that a consumer is quickly able to discover the advantages of the present invention without having to purchase the device.

### V. Soil Modes

Another benefit of the device 100 is that it can be configured to allow a user to toggle between two or more soil-type modes. For example, the device can include at least a first sensing mode wherein the device is calibrated for detection of moisture in a first medium type and at least a second sensing mode wherein the device is calibrated for detection of moisture in a second medium type. For example, the first sensing mode can be calibrated for detection of moisture in a general soil type that includes, for example, loamy soils and clay-bearing soils. In another example, the second sensing mode can be calibrated for detection of moisture in a sandy soil type. In one aspect, sandy soils are unique from general soil types in terms of how quickly water drains out of the soil. As such, the water requirements for plants in the different soil types can be quite different. Providing for different watering requirement depending on different soil types encourages water conservation and promotes plant vigor. Additionally, the device can be configured to allow the user to toggle between the demonstration mode, the first sensing mode mode, and the second sensing mode by depressing the activation button for at least about two seconds, for example.

### VI. Removable Tops

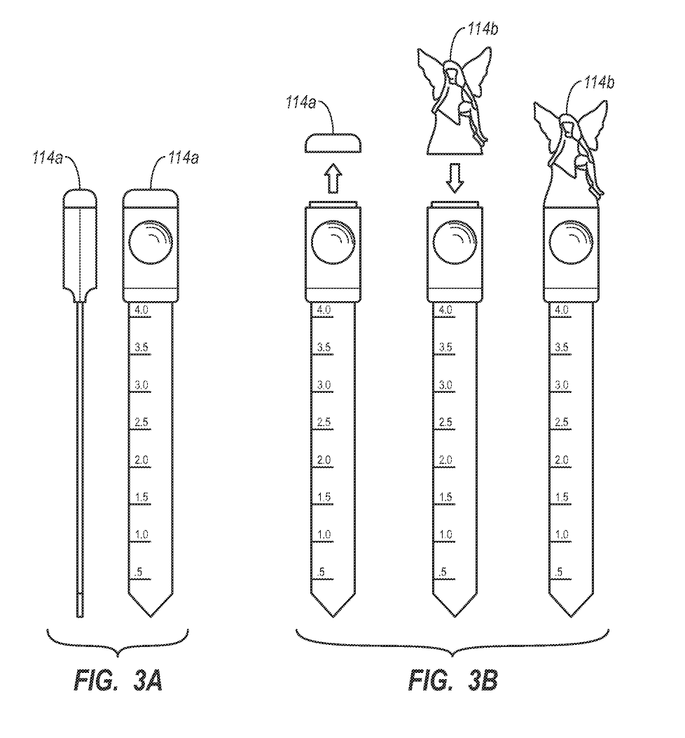

The present invention also provides the added benefit of being customizable, thus enhancing the aesthetic appeal of the device. For example, as shown in at least FIGS. 3A-3B, a top (e.g., 114a) associated with the device may be replaced with various unique decorative tops (e.g., 114b), which may be interchanged to customize the device to the consumer's liking. In the illustrated embodiment, the tops 114 are attached at one end of the device, such as to be disposed above (i.e., covering) the LED. In this manner, the light emitted by the LED below the top 114 exits the housing into the removable top and illuminates the top 114. The tops 114 may be composed of transparent, translucent, and/or opaque materials to allow the light emitted from the LEDs to pass through. As is apparent, any top design which is capable of being attached to the device may be used. In some exemplary embodiments, the interchangeable tops can be shaped as flowers, leaves, plants, faeries, and the like. In some embodiments, the top, such as tops 114a and 114b can be used to conduct light from the LED to a location that is visible to a user.

In FIG. 3B, by way of example only, the wings of the faerie may be configured to receive the light from the diode. As a result, the color of the wings can be used to identify the water content. Thus the top 114a or 114b can be adapted, in some instances, to provide a light pipe from the LED to the desired output location on the top. This allows the display to be adapted to the design of the top.

### VIII. Moisture Monitoring System

In one embodiment, a moisture monitoring system for monitoring soil moisture levels and automatically controlling an irrigation system is described. In general, exemplary embodiments of a moisture monitoring system are concerned with systems and methods for monitoring and controlling an irrigation system based upon moisture or water content of a material containing or supporting plants, shrubs, trees, grass, or the like. For instance, the material may be soil, topsoil, potting soil, soil less growth media, peat, humus, compost, gravel, sand, cellulose material, or any other material within which it is desired to grow plants, shrubs, trees, grass, or the like. The moisture monitoring system described herein can be adapted for indoor and outdoor growing environments.

The system includes a moisture sensing probe that detects the moisture content of the material, such as soil in this exemplary configuration, and transmits moisture level data to a moisture control module. Based on the moisture level data received from the probe, the moisture control module may activate or deactivate one or more irrigation devices to achieve the desired moisture content of the soil. The probe may be configured to provide continuous or periodic indications of the moisture level of the soil surrounding the probe as well as to provide an instant indication of the moisture level on request.

A history of the moisture content can also be maintained by the system. This information can be used, for example, to identify optimum watering times and the like. When additional information is recorded by the system, such as temperature, humidity, and the like, the moisture monitoring system may be able to identify ideal times for watering in order to maintain optimum moisture content in the material while minimizing the use of water. In this manner, the moisture monitoring system can also provide water conservation functionality.

FIG. 4 illustrates an exemplary moisture monitoring system 300. As shown, the system 300 includes a number of moisture monitoring devices 330 for monitoring soil moisture and a number of irrigation devices 310 configured to deliver water, fertilizer, or the desired liquid to the material containing or supporting plants, shrubs, trees, grass, or the like, such as soil in this configuration. The irrigation devices 310 can include, but not limited to, sprinklers, drip lines, or other water delivery structures of an irrigation system or fertilizer delivery systems and the like. The number of moisture monitoring devices 330 and irrigation devices 310 shown are for illustrative purposes only and not as a limitation. The moisture monitoring system 300 may be configured to control only one irrigation device or a complex network of several irrigation devices, such as sprinklers installed in various zones, drip lines installed in various zones, combinations thereof, or the like.

The moisture monitoring devices 330 are inserted in the soil, for example, in a location within the range of the irrigation devices 310. Each moisture monitoring device 330 includes circuitry for detecting the moisture level of the surrounding soil, such as, in one configuration, being based on the dielectric constant of the soil, which is described in further detail herein. In one configuration, the moisture monitoring devices 330 are located such that they provide moisture content indications that are representative of the majority area within the range of the irrigation devices 310. Any number of probes may be implemented in the water monitoring system 300. Further, more than one probe may be used for any particular irrigation device. The information from these probes can be combined when determining the moisture content of a material that is relatively large compared to the probe.

As illustrated in FIG. 3, the moisture monitoring devices 330 are joined by a wire, cable, or another communication line 335 for communicating data indicative of detected moisture level in the form of a signal and optionally include an LED 380 configured to present a visual indication of the moisture content of the soil, for example.

The data indicative of detected moisture level is delivered to the moisture control module 325 of an irrigation control module 320 via a transceiver 360. The moisture control module 325 can include software/hardware modules and circuitry for processing the signal received by transceiver 360 and can optionally include a rain sensor control input 350 to receive data from a rain sensor (not shown). The software/hardware modules and circuitry of the moisture control module 325 can manipulate the signal to identify the moisture content and determine whether additional moisture is needed. In addition to, the current flowing in the transmission line can also or alternatively be sensed and converted to moisture content. In addition, the data (e.g., voltage signal data from the moisture sensing circuitry) can be packaged for delivery to the control module. If moisture is needed, i.e., the moisture content is below a desired threshold level, the moisture control module 325 can signal the irrigation control module 320 to open the one or more valves 315 and allow the irrigation devices 310 to deliver water or another hydrating liquid to the soil. Alternatively, if the moisture content is sufficient, i.e., moisture level is above a desired threshold level, the moisture control module 325 can signal the irrigation control module 320 to not irrigate. In this manner, the circuitry can manipulate the received signal to initiate activation and deactivation of the one or more irrigation devices 310 based upon the detected moisture content.

Over time, the irrigation control module 320 can store data to identify the appropriate amount of time needed to deliver adequate water or liquid and then turn off the valves. Alternatively, the signal to turn the valves off may come from additional signals received from the probes 330. In addition, the various moisture monitoring devices 330 inserted into the soil can be assigned an ID so that specific valves and/or irrigation devices can be triggered so that water is selectively applied to areas that need water while areas having an acceptable water content are not water, thereby conserving water. Furthermore, the moisture monitoring devices 330 can be timed so that a predetermined amount of water is delivered to the soil when the irrigation system is triggered, which also helps to conserve water.

The irrigation control module 320 is connected to one or more irrigation devices 310 via one or more valves 315 and one or more communication lines 340, such as pipes, conduits, etc. The irrigation control module 320 can include the moisture control module 325 and the transceiver 360 for receiving the signal containing moisture level data from the moisture monitoring device 330. As mentioned above, this received moisture level data drives the logic associated with software/hardware modules and circuitry of the moisture control module 325 and/or the irrigation control module 320 to initiate activation or deactivation of the one or more valves 315 to activate or deactivate the one or more irrigation devices 310 for a predetermined period of time or until a desired moisture level indication is received from the probe. As previously stated, the system 300 may learn from the historical measurements of moisture content and adapt the delivery of water or other liquid accordingly, such as by changing the predetermined period of time or by identifying the moisture level that is needed.

In another configuration, such as when the moisture monitoring system 300 includes a legacy or existing sprinkler delivery system with a legacy or existing sprinkler control system, the data from the moisture monitoring device 330 may be received by the transceiver 360 within a separate moisture control module 325′, which optionally receives power from a separate source, such as a battery or secondary source, or from the irrigation control module 320. This moisture control module 325′ can manipulate and analyze the received probe data using associated software/hardware modules and circuitry, and can then deliver data indicative of the moisture content to the input of a rain sensor control input or post 350 of the legacy or existing sprinkler delivery system. This results in the legacy or existing sprinkler delivery system operating and controlling the sprinklers or other irrigation device and enabling a homeowner or business to obtain the benefits of the monitoring system and method taught herein.

Stated another way, data from the moisture monitoring devices 330 and the moisture control module 325′ can delivered to the legacy or existing sprinkler system through the rain sensor control input 350 instead of data or signals from a wired rain sensor. As such, the legacy or existing sprinkler system may be converted to the present system simply by replacing the wired moisture sensor input to the rain sensor control input 350 with an input received from a separate moisture control module 325′ that delivers an input to the rain sensor control input 350.

### IX. Moisture Sensing Circuitry

Referring now to FIGS. 4-9, moisture sensing circuitry is illustrated. The moisture sensing circuitry described herein can be composed entirely of passive components such as diodes, resistors, and capacitors. As such, the moisture sensing circuitry does not require a separate power supply to power active components and the power consumption can be very low, which can lengthen battery life.

It is known that the dielectric constant of materials such as soils varies with water content and that most materials having a higher water content will have a higher dielectric constant. The moisture monitoring device illustrated herein uses moisture sensing circuitry to measure the dielectric constant of a material and produce a signal therefrom that varies according to the magnitude of the dielectric constant. That is, the more water a material contains, the higher its dielectric constant will be and the stronger the signal will be. The strength of the signal can be transmitted digitally (a series of bits to indicate relative strength), in amplitude, by frequency, and the like. The moisture sensing circuitry can thus be configured to measure the dielectric constant of a material and use the measured dielectric constant to detect and quantify the moisture level in the material.

The moisture monitoring device described herein uses moisture sensing circuitry that can create a carrier wave or signal whose magnitude varies depending on the dielectric constant of the surrounding material. In general, the moisture sensing circuitry does not interact directly with the medium (i.e., the circuitry does not directly contact the medium). Instead, the circuitry is designed to propagate a signal through the circuit, the magnitude of which is a function of the dielectric constant of the medium. That is, the magnitude of the carrier wave varies with the dielectric constant of the medium because the dielectric constant of the medium alters the ability to propagate a signal through the circuit, which in turn alters the resistance of the circuit. A higher dielectric constant provides for a stronger carrier stronger signal, which is interpreted by the circuitry in the device as indicating a higher moisture content in the medium.

Several examples of moisture sensing circuitry are shown schematically in FIGS. 5-9. For example, as shown in FIG. 5, a periodic function generator 10 provides the carrier frequency that is coupled to a transmission line probe 13 through a resistive or reactive element 11. The resistive or reactive element and the transmission line form a simple voltage divider whose output voltage is related to the impedance of the transmission line, which is in turn related to the dielectric constant of the medium and the magnitude of the carrier wave.

A voltage divider is a linear circuit that produces an output voltage (Vₒᵤₜ) that is a fraction of its input voltage (Vᵢₙ). Applying Ohm's Law (Formula 1), the relationship between the input voltage, Vᵢₙ, and the output voltage, Vₒᵤₜ, can be found:

$${V}_{out} = \frac{{Z}_{2}}{{Z}_{1} + {Z}_{2}} \cdot {V}_{in} \qquad Formula 1$$

A voltage divider is created by connecting two electrical impedances in series (e.g., Z₁ at 11 and Z₂ at 13 in FIG. 5). The input voltage is applied across the series impedances Z₁ and Z₂ and the output is the voltage across Z₂. Z₁ and Z₂ may be composed of any combination of elements such as resistors, inductors and capacitors.

The electrical impedance of transmission line 13 and the magnitude of the resulting carrier frequency (i.e., the carrier wave) varies according to the dielectric constant of the transmission line probe and correspondingly with the moisture of the material surrounding the transmission line. Because the dielectric constant of the material surrounding transmission line 13 affects the electrical impedance of transmission line 13, Ohm's law tells us that, for a given input voltage provided by a power source (e.g., a 1.5 volt battery), the output voltage that is detected at 14 will vary in proportion to the dielectric constant of the of the material that transmission line 13 is inserted in. The voltage detected at 14 is thus representative of the moisture content of the material that transmission line 13 is inserted in.

In the example shown in FIG. 5, the output of this voltage divider is fed to an Amplitude Modulated (AM) demodulator 12 to remove the carrier, rendering a voltage to the sensor output 14, which is related to the to the moisture of the material surrounding the transmission line probe 13.

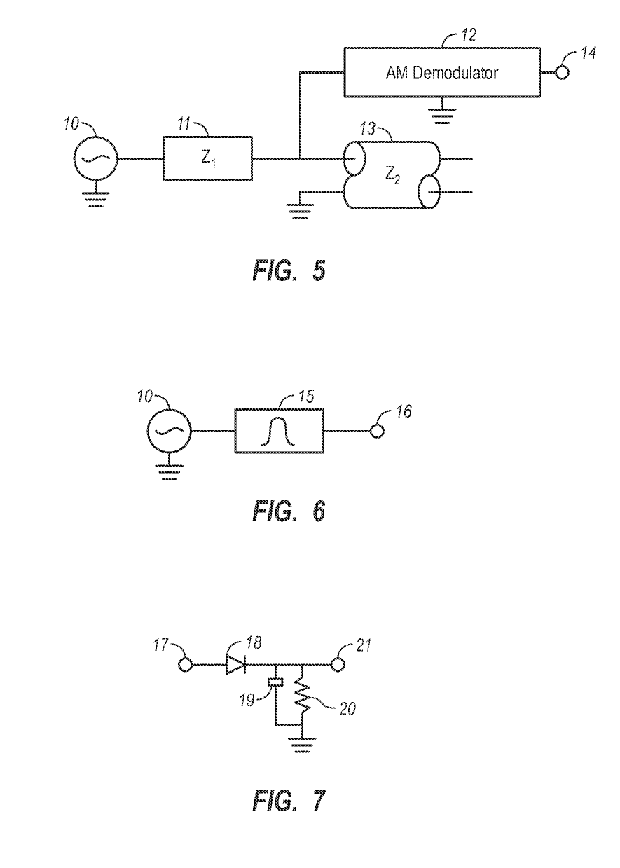

The signal generator 10 may produce any periodic carrier frequency to stimulate the transmission line 13. Many data electronic recording systems already have numerous oscillators or clock sources which can be used for this purpose. For instance, the circuitry described herein can be stimulated by any periodic signal including, but not limited to, sine, square, and triangular waves. If a non-square periodic signal is available in the systems, this signal can be used to stimulate the transmission line without the extra cost associated with adding a square-wave oscillator. These periodic waves can be band pass filtered or low pass filtered if the desired frequency is the fundamental frequency of the waveform, to produce a single frequency carrier. Thus, in the embodiment of FIG. 6, a filter circuit 15 is used to produce a single carrier frequency.

Turning to the reactance of the device, the reactance of transmission lines alternates between negative and positive values every quarter wavelength of the carrier frequency, as the transmission line length increases. For example, a transmission line with an open circuit load has a negative reactance when the length of the line is less than a quarter wavelength of the carrier, and positive from above a quarter wavelength to below one half a wave length, and so on. The even quarter wavelength nodes are resonance points. Thus, in practice the carrier and the length of the transmission line can be chosen for a desired reactance point. For example, the length of an open load transmission line could be chosen to be less than one quarter of a wavelength such that the reactance is negative. For applications where it is desired that the length of the transmission line be minimized, a higher carrier frequency could be used.

The resistive or reactive element 11 can be composed of a single resistor, but other reactive elements such as inductors or capacitors, or combinations thereof, can be used.

Many types of AM demodulators can be used, from specialized integrated circuits, to simple passive demodulators. One such passive demodulator is illustrated in FIG. 7. This is also known as a peak detector, and can include an input 17, a rectifier 18, a parallel connected capacitor 19, and resistor 20. The peak detector removes the carrier frequency and renders a waveform on the output 21, which tracks the envelope of the modulating frequency. Because passive components can be used, in one configuration, no separate power supply is needed to power the electronic circuit, and the voltage supply only need be slightly greater than the forward voltage of the rectifying diode, allowing the circuit to use a very low voltage carrier. This circuit consumes very little power, making it ideal for remote battery operated applications. It will be understood, that in other configurations active components may be used.

The output of the sensor can be digitized using various methods, including the use of an analog to digital converter (ADC). This digitized signal can be passed to a microcontroller or computer system for further processing, such as averaging to remove noise and determination of the moisture content. The relationship between the voltage from the demodulator and the water moisture can be derived from a lookup table in the microcontroller that contains known relationship values for voltage and moisture content. It may alternatively be determined by the computer system by computing the reactance of the transmission line element given the known values of the carrier amplitude, and the impedance of the reactive or resistive element 11. Once the reactance of the probe is known the dielectric constant and correspondingly the water content of the bulk material may then be identified.

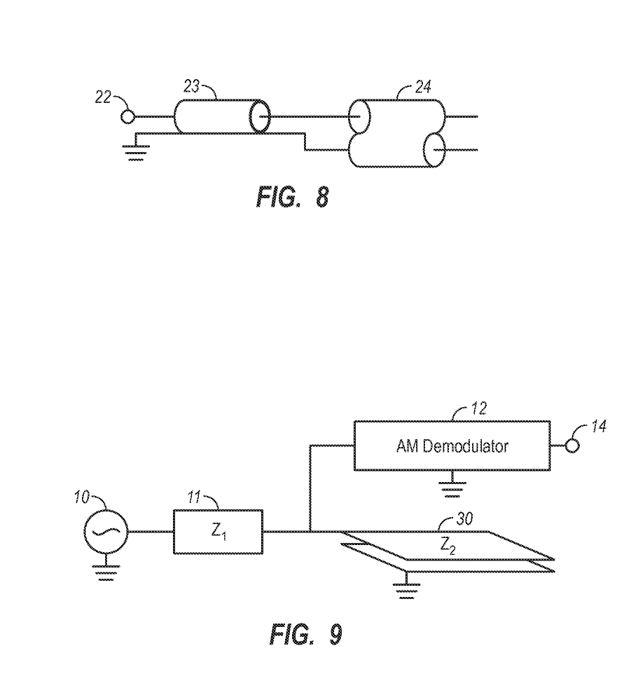

Many types of transmission line based probes can be used for the device. FIG. 8 shows a multi-segmented transmission line, wherein a transmission line that is insensitive to the dielectric constant of the medium through which it passes 23, such as coax, is used to couple the carrier frequency to the second transmission line which is sensitive to the carrier frequency 24. This is useful in applications where the sensor probe needs to be placed remotely away from the sensor electronics.

A block diagram of another alternative embodiment is illustrated in FIG. 9. A periodic function generator 10 provides a carrier frequency that is coupled to a capacitive probe 30 through a resistive or reactive element 11. The resistive or reactive element 11 with the transmission line forms a simple voltage divider, whose output voltage is related to the impedance of the capacitor. The magnitude of the carrier frequency can vary according to the dielectric constant of the material in which the probe is inserted. The output of this voltage divider can be fed to an AM demodulator 12 for the purpose of removing the carrier, and rendering a voltage to the sensor output 14 which is related to the moisture of the material surrounding the transmission line probe.

As with the other embodiments discussed herein, this embodiment may similarly make use of a peak detector for the AM demodulator, and a filter circuit for the carrier signal.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A device for measuring moisture content in a material, the device comprising:
a probe having circuitry adapted for detecting moisture content of a material when the probe is inserted substantially vertically into the material, the circuitry being configured to produce a signal that corresponds to the moisture content of the material;
a button configured to actuate a driver, the driver being adapted to receive the signal from the probe and generate a current in response to being actuated by the button, the current having a magnitude that is proportional to the magnitude of the voltage; and
one or more display devices actuated by receiving the current from the driver in order to provide a readout therefrom that is proportional to the magnitude of the current and that represents the moisture content of the material.

2. The device of claim 1, wherein moisture content includes water content and associated mineral content in the material.

3. The device of claim 1, the probe further including:
a distal end including an active zone that includes at least a portion of the moisture sensing circuitry, the active zone being configured for detecting moisture content of the material; and
an inactive zone disposed proximal to the active zone,
wherein the active zone and at least a portion of the inactive zone are inserted substantially vertically into the material.

4. The device of claim 3, wherein the device is configured to provide a readout proportional to an average of the moisture content in the active zone.

5. The device of claim 1, the material being at least one of soil, topsoil, potting soil, soil less growth media, peat, humus, compost, gravel, sand, or cellulose material.

6. The device of claim 1, the current being proportional to the moisture content of the material.

7. The device of claim 1, the one or more display devices including at least one of one or more Light Emitting Diodes (LEDs) or one or more Liquid Crystal Displays (LCDs), the one or more LEDs or the one or more LCDs providing a readout that represents the moisture content of the material.

8. The device of claim 6, the one or more LEDs including at least one LED having a color that represents the moisture content of the material.

9. The device of claim 8, further comprising at least one LED that is configured to be illuminated when the moisture content of the material exceeds a specified threshold value indicating that the material contains excess moisture.

10. The device of claim 1 further comprising a selectively removable decorative top attached to the device, the decorative top being disposed over the one or more display devices.

11. The device of claim 10, wherein the decorative top is selectively removable and interchangeable with one or more other decorative tops.

12. The device of claim 1 further comprising:
packaging for receiving the device, the packaging including a plurality of openings adjacent at least the probe and the button when the device is received therein, the plurality of openings allowing demonstration of the device without removing the device from the packaging.

13. The device of claim 1, further comprising:
a demonstration mode that allows a user to temporarily actuate the device by pressing the button while grasping the probe with one or more fingers, such that the actuation of the device causes the circuitry to generate a signal to provide an indication of the moisture content of the user's one or more fingers;
at least a first sensing mode calibrated for detection of moisture in a first medium type; and
at least a second sensing mode calibrated for detection of moisture in a second medium type,
wherein the device is configured to allow the user to toggle between the demonstration mode, the first test mode, and the second test mode by depressing the button for at least about two seconds.

14. A moisture monitoring system, comprising:
an irrigation control module communicatively coupled to one or more valves and one or more irrigation devices via one or more communication lines;
one or more probes for detecting moisture content in a material when each of the one or more probes is inserted substantially vertically into and at least partially submerged in the material, each of the one or more probes including:
moisture sensing circuitry being configured to produce a first signal that varies in magnitude with the moisture content of the material;
a transceiver communicably coupled to the moisture sensing circuitry, the transceiver being configured for receiving the first signal and transmitting a second signal; and
a moisture control module in communication with the irrigation control module and the one or more probes, the moisture control module including processing circuitry configured for receiving the second signal from the first transceiver and manipulating the second signal for delivery to the irrigation control module to initiate activation and deactivation of the one or more irrigation devices based upon the detected moisture content.

15. The system of claim 14, each of the one or more probes including:
a distal end including an active zone that includes at least a portion of the moisture sensing circuitry, the active zone being configured for detecting moisture content of the material; and
an inactive zone disposed proximal to the active zone,
wherein the active zone and at least a portion of the inactive zone are inserted substantially vertically into the material.

16. The system of claim 15, wherein each of the one or more probes is configured to provide a first signal proportional to an average of the moisture content in the active zone.

17. The system of claim 14, further comprising one or more of the probes, the moisture sensing circuitry, the first transceiver, and/or the moisture control module being configured to activate the one or more irrigation devices so as to apply a selected amount of water to the medium based on a specified threshold value.

18. The system of claim 14, further comprising one or more of the probes, the moisture sensing circuitry, the first transceiver, and/or the moisture control module being configured to deactivate the one or more irrigation devices based on a specified signal magnitude when the medium reaches a selected moisture level.

19. The system of claim 18, further comprising delay circuitry that delays deactivation of the one or more irrigation devices for a selected period of time when the medium reaches the selected moisture level.

20. A method for measuring moisture content, comprising:
providing one or more probes for detecting moisture content in a material, each of the one or more probes including:
moisture sensing circuitry being configured to produce a signal that varies in magnitude with the moisture content of the material; and
a switch coupled to the moisture sensing circuitry and an driver, the driver being adapted to receive the signal from the moisture sensing circuitry, generate current therefrom that is proportional to the magnitude of the signal, and transmit the current to one or more display devices;
vertically inserting and partially submerging the one or more probes in the material; and
triggering the switch to activate the driver so as to receive the signal from the moisture sensing circuitry;
converting the signal to a current having a magnitude that is proportional to the signal; and
transmitting the current to the one or more display devices for activating the one or more display devices, wherein activating the one or more display devices provides an instantaneous indication of the moisture content of the material.

21. The system of claim 20, each of the one or more probes including:
a distal end including an active zone that includes at least a portion of the moisture sensing circuitry, the active zone being configured for detecting moisture content of the material; and
an inactive zone disposed proximal to the active zone,
wherein the active zone and at least a portion of the inactive zone are inserted substantially vertically into the material.

22. The method recited in claim 21, wherein the signal is proportional to an average of the moisture content in the active zone.

23. The method recited in claim 21, wherein the one or more display devices remain illuminated for a defined duration of time after the button is pressed.

24. The method recited in claim 20, the one or more display devices including at least one of one or more Light Emitting Diodes (LEDs) or one or more Liquid Crystal Displays (LCDs), the one or more LEDs including at least one LED having a color that represents the moisture content of the material.

25. The method recited in claim 24, further comprising at least one LED that is configured to be illuminated when the moisture content of the material exceeds a specified threshold value indicating that the material contains excess moisture.
